(19) United States
(12) Patent Application Publication
(10) Pub. No.: US 2017/0250223 A1
(43) Pub. Date: Aug. 31, 2017

(54) A RESISTIVE RANDOM-ACCESS MEMORY IN PRINTED CIRCUIT BOARD

(71) Applicant: HEWLETT-PACKARD DEVELOPMENT COMPANY, L.P., Houston, TX (US)

(72) Inventors: Ning GE, Palo Alto, CA (US); Vincent Nguyen, Houston, TX (US); Jianhua Yang, Palo Alto, CA (US); Chanh Hua, Houston, TX (US); Lidia Warnes, Roseville, CA (US); David B. Fujii, Boise, ID (US)

(73) Assignee: HEWLETT-PACKARD DEVELOPMENT COMPANY, L.P., Houston, TX (US)

(21) Appl. No.: 15/521,588

(22) PCT Filed: Nov. 19, 2014
(86) PCT No.: PCT/US2014/066292

§ 371 Date: Apr. 24, 2017

(51) Int. Cl. H01L 27/24; H05K 1/16; H05K 3/06; H01L 45/00

(52) U.S. Cl. CPC H01L 27/2463; H01L 45/1233; H01L 45/1253; H05K 1/16; H01L 45/1608; H01L 45/145; H01L 45/146; H01L 45/147; H01L 45/08; H05K 3/061; H05K 2201/10159

(57) ABSTRACT

Provided in one example is an article. The article including: a first electrode; a switching layer disposed over at least a portion of the first electrode, the switching layer including a metal oxide; and a second electrode disposed over at least a portion of the switching layer. The first electrode, the switching layer, and the second electrode are parts of a resistive random-access memory, and one or both of the first electrode and the second electrode is a part of a layer of a printed circuit board.

### BACKGROUND

A resistive random-access memory is a device that may be programmed to different resistive states by applying a programming energy, for example, a voltage or current pulse. This energy generates a combination of electric field and thermal effects that may modulate the conductivity of both non-volatile switch and nonlinear select functions in a memristive element, After programming, the state of the resistive random-access memory may be read and remains stable over a specified time period.

### BRIEF DESCRIPTION OF THE DRAWINGS

The drawings are provided to illustrate various examples of the subject matter described herein related to a resistive random-access memory and are not intended to limit the scope of the subject matter. The drawings are not necessarily to scale.

FIG. 1A-1C are schematics showing one example of a memristor, a memristor in a crossbar design, and a crossbar array of memristors, respectively.

FIG. 2 shows a schematic showing one example of a printed circuit board (“PCB”) including a memristor described herein.

FIG. 3 shows a flowchart showing one example of a process of making a memristor described herein.

FIG. 4 shows a flowchart showing another example of process of making a memristor described herein.

FIG. 5A-5H show schematics illustrating, in one example, the different stages/processes involved in one method of making a memristor described herein.

FIG. 6A-68 show schematics showing one example of a memristor described herein in an aerial view and a cross-sectional view.

### DETAILED DESCRIPTION

Following. below are more detailed descriptions of various examples related to a resistive random-access memory, particularly a resistive random-access memory embedded in a printed circuit board (“PCB”). The term “PCB” herein in this disclosure (hereinafter “herein” for short, unless explicitly stated otherwise) may also encompass a printed circuit assembly (“PCA”). The various examples described herein may be implemented in any of numerous ways.

Provided in one aspect of the examples is an article, including: a first electrode; a switching layer disposed over at least a portion of the first electrode, the switching layer including a metal oxide; and a second electrode disposed over at least a portion of the switching layer; wherein the first electrode, the switching layer, and the second electrode are parts of a resistive random-access memory, and one or both of the first electrode and the second electrode is a part of a layer of a printed circuit board.

Provided in another aspect of the examples is a method of manufacturing, including: forming a first electrode from a portion of a first layer of a printed circuit board; forming a switching layer over a portion of the first electrode, the switching layer including a metal oxide; and forming over a portion of the switching layer a second electrode, wherein the second electrode is a part of a second layer of the printed circuit board; wherein the first electrode, the switching layer, and the second electrode are parts of a resistive random-access memory embedded in the printed circuit board.

Provided in another aspect of the examples is a method of manufacturing, including: disposing a resist over a cladding layer including a first metal-containing material, the cladding layer disposed over a substrate that is one layer of a printed circuit board; etching, using a first mask, at least a portion of the resist and a portion of the cladding layer to form a first electrode, which is disposed over the substrate; disposing an oxide layer including a metal oxide over at least a portion of the first electrode and a portion of the substrate; disposing a second metal-containing material over the oxide layer; and etching, using a second mask, at least a portion of the second meta-containing material and a portion of the oxide layer to form respectively a second electrode and a switching layer, the second electrode disposed over the switching layer including the metal oxide, the switching layer disposed over the first electrode, whereby a resistive random-access memory including the first electrode, the switching layer, and the second electrode is formed embedded in the printed circuit board.

### Resistive Random-Access Memory

The term “resistance memory element” herein may refer to programmable non-volatile memory where the switching mechanism involves ionic motion, including valance change memory, electrochemical metallization memory, and others. Resistive memory elements may be used in a variety of applications, including non-volatile solid state memory, programmable logic, signal processing, control systems, pattern recognition, and other applications. One example of a resistance memory element is resistive random-access memory (“ReRAM”). ReRAM works by changing the resistance across a dielectric solid-state material that may include a memristor. Examples of ReRAM include a memristor, a phase-change memory, a conductive-bridging RAM, and a spin-transfer torque RAM. Merely to facilitate the explanation and for the sake of convenience, a memristor is employed herein to describe an ReRAM; however, it is appreciated that the description may be applicable to other types of ReRAM.

Memristors, or memristive devices such as ReRAM, are devices that may be used as a component in a wide e of electronic circuits, such as memories, switches, and logic circuits and systems. In a memory structure, a memristive crossbar array (“MCA”) (of memristors) may be employed. For example, when employed as a basis for memories, a memristor may be employed to store bits of information, in the form of 1 or 0, corresponding to whether the memristor is in its high or low resistance state (or vice versa). When employed as a logic circuit, a memristor may be employed as configuration bits and switch in a logic circuit similar to a Field Programmable Gate Array, or may be the basis for a wired-logic Programmable Logic Array. It is also possible to employ memristors capable of multi-state or analog behavior for these and other applications.

When employed as a switch, the memristor may either be in a low resistance (closed) state or high resistance (open) state in a cross-point memory. The resistance of a memristor may be changed by applying an electrical stimulus, such as a voltage or a current, through the memristor. Generally, at least one channel may be formed that is capable of being switched between two states—one in which the channel forms an electrically conductive path (“ON”) and one in which the channel forms a less conductive path (“OFF”). In some other cases, conductive paths represent “OFF” and less conductive paths represent “ON.”

An ReRAM, such as a memristor, may include any suitable number of components. The memristor may include a switching layer sandwiched between two electrodes. The switching layer may be sandwiched horizontally between the two electrodes in one (horizontal) layer, or the switching layer may be sandwiched vertically between the two electrodes in multiple (horizontal) layers. The switching layer may be an oxide. In one example, the switching layer is a continuous oxide film. The memristor, including any or all of the bottom electrode, the switching layer, and the top electrode, may be of micrometer-sized. The memristor (including any or all of the components thereof) may have the largest dimension thereof being larger than or equal to about 1 μm and less than 1 mm e.g., between about 0.5 μm and about 500 μm, between about 1 μm and about 100 μm, etc. Other dimension values are also possible. Depending on the context, the dimension in this instance may refer to a width or a length.

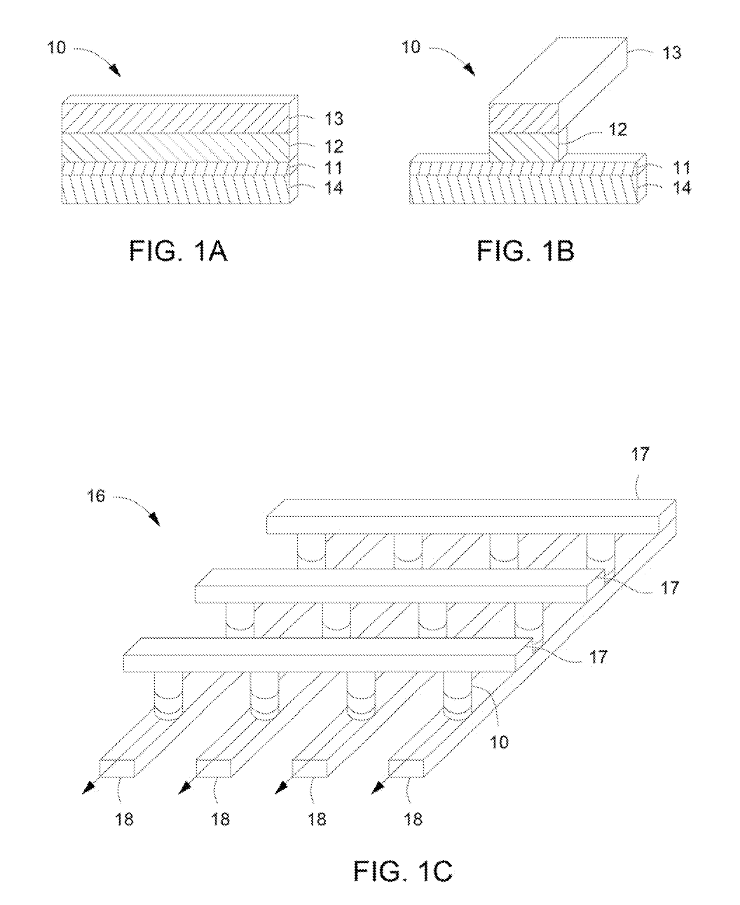

FIG. 1A is a schematic showing one example of a memristor 10 and some components thereof, and FIG. 1B is a schematic showing one example of a memristor 10 in a crossbar design (e.g., in an MCA). In the examples as shown in FIGS. 1A and 1B, the memristor 10 includes a first (bottom) electrode 11, a switching layer 12 disposed over at least a portion of the first electrode 11, and a second (top) electrode 13 disposed over at least a portion of the switching layer 12. The terms “first,” “second,” etc. herein are employed merely to denote the objects they respectively describe as separate entities, and are not meant to connote any chronological order unless otherwise explicitly specified. As shown in FIGS. 1A and 1B, the first electrode layer is disposed over a substrate 14. The switching layer 12 may be disposed over an entire surface (or multiple surfaces) of the bottom electrode 11, or it may be disposed over a portion of one (or multiple) surface(s) (as shown in FIG. 1B). Similarly, the top electrode 13 may be disposed over a portion of the switching layer 12 or an entire surface (of multiple surfaces) of the switching layer 12 (as shown in FIG. 1B). It is noted that in FIGS. 1A and 1B, the memristor 10 is shown as having multiple horizontal layers vertically stacked together—a second electrode 13 disposed vertically over a switching layer 12, which is disposed vertically over a first electrode 11. However, as noted above, a memristor need not have a vertical multi-layer configuration, and instead may have one (horizontal) layer having a second electrode 13, the switching layer 12, and the first electrode stacked horizontally side-by-side (not shown).

The bottom electrode 11 and top electrode 13 each may contain an electrically conductive material. The conductive material may be a metal-containing material. For example, the conductive material may be one of a pure metal, a metal alloy, a compound containing a metal element, and combinations thereof. The term “element” herein may refer to the chemical symbol found on a Periodic Table. The compound may be, for example, an oxide, a nitride, etc. The materials of the bottom electrode and the top electrode may be the same as or different from each other. One or both of the bottom electrode and the top electrode may be selected from the group consisting of platinum, copper, aluminum, titanium, tantalum, cobalt, nickel, molybdenum, tungsten, chromium, niobium, hafnium, zirconium, ruthenium, indium, tin, iridium, and combinations thereof, or an alloy, or a nitride, or an oxide of any of the foregoing. In one example, the bottom electrode and/or the top electrode is at least one of TiN, TaN, NbN, HfN, ZrN ITO, RuO₂, IrO₂, Al, Ta, Cu, Co, Ni, Nb, Mo, W, Hf, Zr, and Cr.

The bottom electrode 11 and the top electrode 13 described herein may have any suitable geometry, including size. Depending on the context and geometry, the term “size” may refer to length, width, thickness, diameter, etc. The bottom electrode and the top electrode may have the same geometry (including size) or different geometries (including sizes). One or both of the top electrode and the bottom electrode may have a thickness that is less than or equal to about 1 μm—e.g., less than or equal to about 800 nm, about 600 nm, about 400 nm, about 200 nm, about 100 nm, or smaller. Other thickness values are also possible. In one example, one or both of the bottom electrode and the top electrode has a thickness of between about 400 nm and about 500 nm. In another example, one or both of the bottom electrode and the top electrode has a thickness of between about 100 nm and about 300 nm.

The switching layer 12 sandwiched between the bottom electrode 11 and top electrode 13 may be a metal oxide, a metal nitride, or both. In one example, the switching layer 12 is a metal oxide. The metal element of the oxide and the nitride may be a transition metal element or a non-transition metal element. In one example, the switching layer 12 is a metal oxide that is selected from the group consisting of tantalum oxide, zinc oxide, zirconium oxide, gallium oxide, hafnium oxide, titanium oxide, tungsten oxide, copper oxide, vanadium oxide, iron oxide, strontium titanate, lithium niobate, niobium oxide, aluminium copper silicon metal oxide, and combinations thereof. In one example, the switching layer 12 includes a transition metal oxide, such as tantalum oxide, titanium oxide, yttrium oxide, hafnium oxide, niobium oxide, zirconium oxide, and the like. In another example, the switching layer 12 includes a non-transition metal oxide, such as aluminum oxide, calcium oxide, magnesium oxide, dysprosium oxide, lanthanum oxide, silicon dioxide, and the like. In another example, the switching layer 12 includes a transition metal nitride, such as aluminum nitride, gallium nitride, tantalum nitride, silicon nitride, and the like. The aforedescribed oxides and nitrides may be full (stoichiometric) oxides or defect oxides. In one example of a defect oxide, the deficiency in oxygen (or nitrogen) creates oxygen (or nitrogen) vacancies, which then may migrate under application of an electric field. The metal oxide may be at least one of ZrO₂, Gd₂O₁, HfOₓ (1<x≦2), TiOₓ (1<x≦2), SiO₂, WOₓ (0<x≦3), CuO_{y} (0<y≦1), TaO_{z} (0<z≦2.5), VOₓ (1<x≦2), MFe₂O₄ (M may be any one of Mn, Fe, Co, and Ni), SrTiO_{3-c}N_{d} (0≦c<3, d=2c/3), LiNbO₂, and Nb₂O₅.

The switching layer 12 may additionally be an electrically conductive material, such as a metal, metal alloy, and the like. In one example, the electrically conductive material is dispersed within a matrix including the aforedescribed oxide/nitride material for the switching layer. In another example, the electrically conductive material is the matrix and the oxide/nitride material is dispersed within the matrix.

Because the bottom 11 and top 13 electrodes ay be a metal-containing material, in one example one or both of these electrodes have an electrode interface layer disposed over the electrode surface (not shown in the figures)—for the bottom electrode between the bottom electrode surface and the switching layer, and for the top electrode between the top electrode surface and the switching layer. The interface layer may be an oxide and/or nitride of the metal-containing material of the electrode. One or both of the bottom electrode interface layer and the top electrode interface layer may be a nitride, an oxide, or both, of one of copper, aluminium, titanium, tantalum, cobalt, zinc, nickel, iron, yttrium, silicon, gallium, molybdenum, tungsten, chromium, niobium, hafnium, zirconium, ruthenium, platinum, and iridium, and combinations thereof.

The bottom and top electrode interface layers may be disposed over a portion of at least one surface of the respective bottom and top electrodes or the entire surface thereof. The bottom and top electrode interface layers may have any suitable thickness value. The bottom electrode interface layer may have the same or different thickness from the top electrode interface layer. For example, either or both of the bottom and top electrode interface layers may have a thickness that is less than or equal to about 100 nm e.g., less than or equal to about. 80 nm, about 60 nm, about 40 nm, about 20 nm, about 10 nm, or smaller. Other thickness values are also possible

The bottom electrode 11 may be disposed over a substrate 14, as shown in FIGS. 1A and 1B. The substrate 14 may be at least one of a glass-reinforced epoxy laminate and a ceramic. The glass-reinforced epoxy laminate may include any suitable type of glass, such as silica, woven fiberglass, and epoxy. The laminate may be a thermoset laminate or a thermoplastic laminate, or both. In one example, the laminate is a 25N/25FR® from Arlon, Inc., Calif., USA. In another example, the laminate is at least one of Nelco™ N6000, Isola Gigaver® 210, and Polyclad PCL-LD-621, all of which from Asahi Kasei Chemicals Corp., Japan. In another example, the laminate is MCL-LX-67 from Hitachi Chemical Co. America, Ltd, USA. In another example, the laminate is an RO4000e series laminate, such as 4350B-4403 from Rogers Corporation, USA. In another example, the laminate is 35RF/TP-35 from Taconic, USA. In one example, the laminate is FR-4. The FR-4 may be a low loss and halogen-free material, such as NPG-150N (from Nan Ya Plastic Corporation, Taiwan), EM285 RTF (by Elite Material Co., Ltd., Taiwan), and TU747 RFT (from Taiwan Union Technology Corp., Taiwan). The ceramic may be an oxide, a nitride, an oxynitride, etc. In one example, the substrate is not a wafer, such as a silicon-containing wafer. In one example, the substrate is at least substantially free, such as completely free, of elemental silicon.

FIG. 1C provides a schematic of a crossbar array (MCA) 16 of memristors 10. As shown in this figure, each memristor 10 is sandwiched between two conductive layers 17 and 18, which are conductive interconnects that may be a metal-containing material, including a pure metal, a metal alloy, a metal compound, and the like. The memristor 10 may be any of the memristors described herein. In one example, the crossbar 16 is embedded in a PCB.

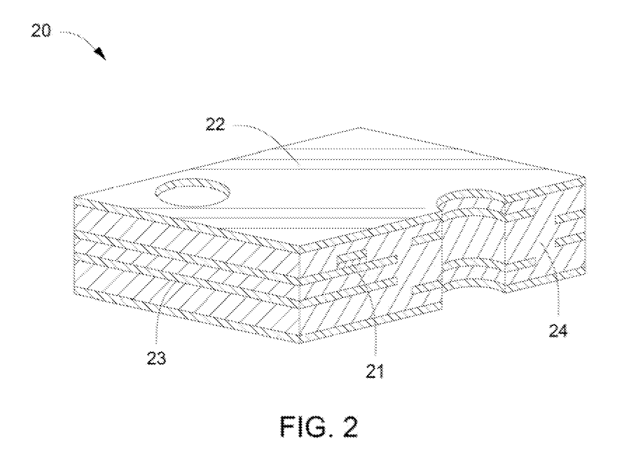

The ReRAM, with memristor as one example, described herein may be embedded in a printed circuit board. FIG. 2 is a schematic illustrating such an example. In the figure, memristor 21 is embedded in a PCB 20, with at least one of the components of the memristor 21 being a part of the PCB 20. It is noted that in some instances, a plurality of memristors described herein may be embedded in on PCB. The PCB 20 contains different layers, including at the top a copper foil 22 layer and a plurality of inner layers 23. At least one inner layer 23 may be a memristor 21 (or any type of ReRAM) described herein. As a part of the inner layer 23, a laminate (e.g., FR-4) commonly employed in a PCB is present.

### Method of Manufacturing

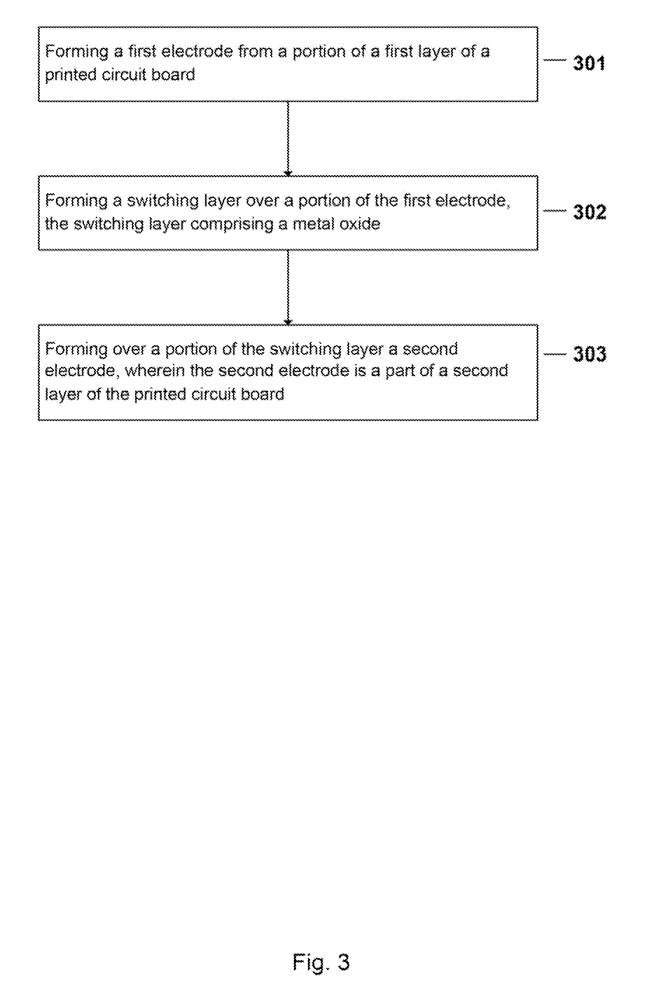

The ReRAM, with memristor as one example, described herein may be manufactured by a method including any suitable processes. FIG. 3 is a flowchart showing the processes involved in one example of such a method. As shown in FIG. 3, a memristor described herein is made first by forming a first electrode from a portion of a first layer of a printed circuit board (301). The forming may involve lithography. In this instance, the switching layer is a metal oxide. Subsequently, a switching layer is formed over at least a portion of the first electrode (302). The formation of the switching layer may involve any of chemical vapor deposition, physical vapor disposition, oxidation, and a sol-gel process. Thereafter, the method may include a process of forming over at least a portion of the switching layer a second electrode (303). The forming may involve lithography. The second electrode may be a part of a second layer of the printed circuit board. The resultant memristor may be embedded in the PCB. It is noted that the first electrode, the switching layer, and the second electrode may be any of those described herein. It is also noted that any of the processes in the method described herein may be repeated to make a plurality of the memristors in the PCB. The aforementioned lithography may involve any suitable lithographical techniques, including, for example, photolithography.

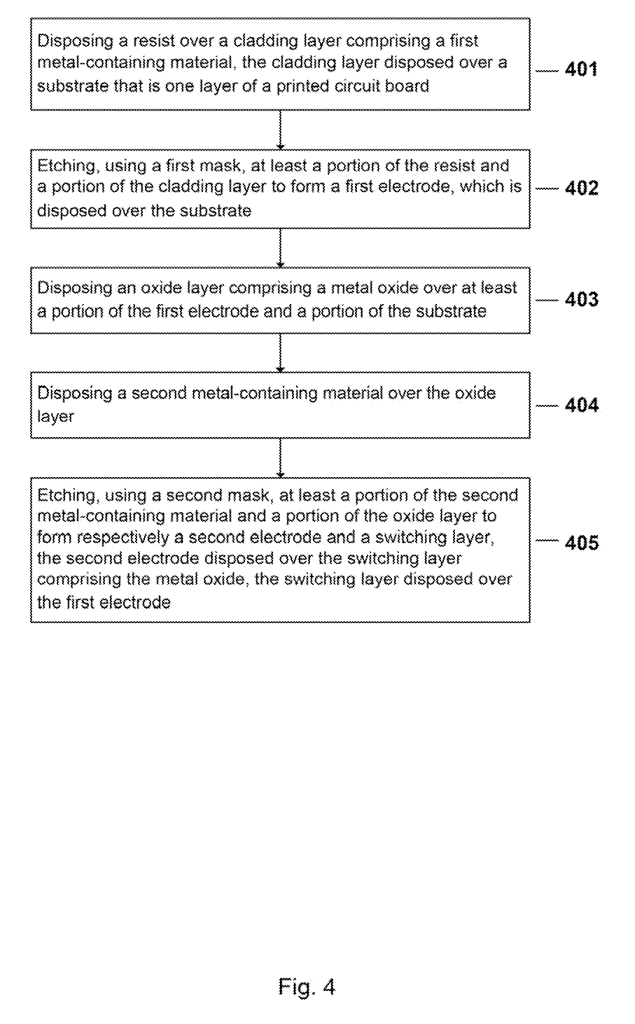

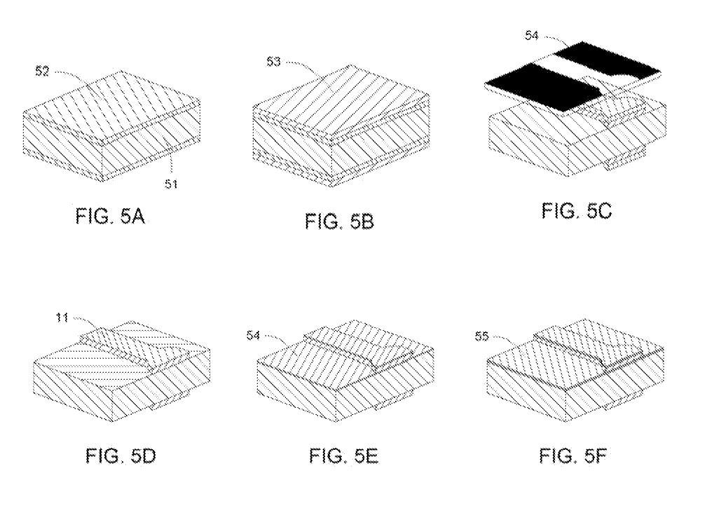

FIG. 4 is a flowchart showing the processes involved in another example of a method of making a memristor described herein, and FIG. 5 illustrates the different stages/processes, such as those shown in FIG. 4, further with schematics. As shown in FIG. 4, the method may include disposing a resist over a cladding layer including a first metal-containing material, the cladding layer disposed over a substrate that is one layer of a printed circuit board (401). The resist may be a photoresist. As further shown in FIG. 5A, the cladding layer 52, which may be a conductive material, such as any material described herein as suitable for an electrode, may be disposed over a substrate 51, which may be any of the substrates described herein. It is noted that the cladding layer may also be a layer of the PCB. Also, an interface layer (of any of the suitable interface layer materials described herein) may be formed over the cladding layer 52—the interface layer is not shown in the figure, but the formation of the interface layer is described further below.

The method as shown in FIG. 4 then may include etching, using a first mask, at least a portion of the resist and a portion of the cladding layer to form a first electrode, which is disposed over the substrate (402). As further shown in FIGS. 5B-5C, a resist 53 is disposed over the cladding layer (FIG. 5B); thereafter a portion of the resist 53 and a portion of the cladding layer 54 (also a portion of the interface layer should one be present) are etched away, such as by lithography (e.g., photolithography)—the lithography may involve a mask (e.g., artwork mask) (FIG. 5C). As further shown in FIG. 5D, the remaining resist is removed to expose a part formed from the etched cladding layer this part then becomes the first electrode 11. The aforementioned resists may include any suitable material, and may be, for example, a photoresist.

The method as shown in FIG. 4 then may include disposing an oxide layer including a metal oxide over at least a portion of the first electrode and a portion of the substrate (403). As further shown in FIG. 5E, an oxide layer 54 may be disposed over a surface of the first electrode and the substrate. As described above, the disposition and formation of the oxide layer may involve any of chemical vapor depositing, physical vapor disposition, oxidation, and a sol-gel process. The method as shown m FIG. 4 then may include disposing a second metal-containing material over the oxide layer (404). As further shown in FIG. 5F, a conductive, metal-containing material 55, which may be any of the materials described herein as suitable for electrode, may be disposed over the oxide layer 54. Although not shown in the figures, a top electrode interface layer (of any of the suitable interface layer materials described herein) may be formed from the metal-containing material 55 and be located between the metal-containing material 55 and the oxide layer 54.

The method as shown in FIG. 4 then may include etching, using a second mask, at least a portion of the second metal-containing material and a portion of the oxide layer to form respectively a (top) second electrode and a switching layer, the second electrode disposed over the switching layer including the metal oxide, the switching layer disposed over the first electrode (405). It is noted that should a top electrode interface layer be present, the interface layer would also be etched. As further shown in FIG. 5G, a second mask 56 (e.g., artwork mask) is disposed over the second conductive metal-containing material 55. Although not shown, it is noted that during the process as shown in FIG. 5G, an additional resist may be employed. As further shown in FIG. 5H, with the mask 56 used in FIG. 5G, a portion of the second metal-containing material 55 and a portion of the oxide layer 54 may be etched away to form respectively a second electrode 13 and a switching layer 12. The first electrode 11, the switching layer 12, and the top electrode 13 then become parts of a memristor 10, which is embedded in the PCB. The aforementioned resists may include any suitable material, and may be, for example, a photoresist.

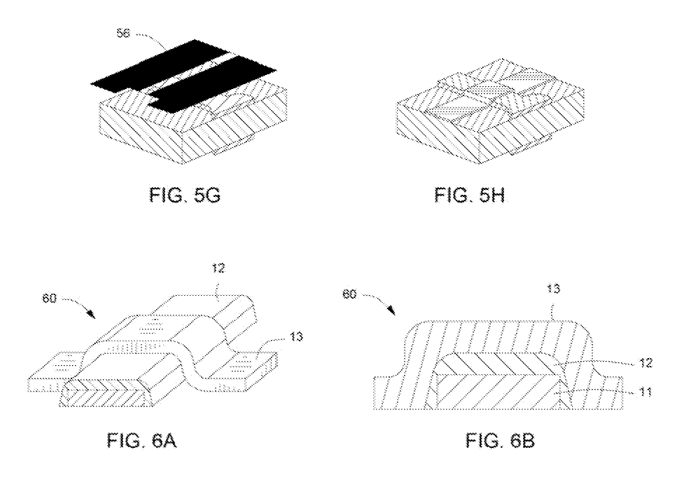

FIG. 6A illustrates one memristor 60 and its components fabricated using the method as described in FIGS. 5A-5H, and FIG. 6B illustrates cross-sectional view of this memristor. It is also noted that any of the processes in the method described herein may be repeated to make a plurality of the memristors in the PCB. Also, the fabrication method described herein may further include processes to manufacture the other components of the PCB so as to manufacture the PCB as a whole.

In one example, the formation of the switching layer may additionally involve forming at least one conductive channel in the switching material between the two electrodes. Thus, the formation may involve electroforming, which includes applying a sufficiently high (threshold) voltage across the electrodes for a sufficient length of time to cause a nucleation and formation of a localized conductive channel (or active region) in the switching material. The threshold voltage and the length of time needed for the forming process may depend upon the type of material used for the switching material, the first electrode, and the second electrode, and the device geometry.

Additionally, the electrode interface layers (of the top and/or bottom electrode) described may be formed by any suitable technique. The interface layers may be formed by a deposition process or by chemically modifying the surface of the electrode. In one example, this formation involves oxidizing the metal in the electrode to create a surface oxide layer. In another example, this formation involves depositing and/or sputtering an oxide or nitride layer over the electrode surface. The interface layer may include any of the materials described herein. In one example, the interface layer may be at least one of HfOx (0<x<2.5), TaOx (0<x<2.5), ZrOx (0<x<2), ZnOx (0<x<2), NiOx (0<x<1.5), FeOx (0<x<1.5), CoOx (0<x<1.5), YOx (0<x<1.5), SiOx(0<x<2), WOx (0<x<3), NbOx (0<x<2.5), TiOx (0<x<2), AlOx (0<x<1.5), MoOx (0<x<3), GaOx (0<x<1,5), AlNx (0<x<1.5), GaNx (0<x<1,5), and AlGaNx (0<x<1.5).

### Applications

The ReRAM, with memristor as one example, described herein may have several beneficial properties, thereby alloying the ReRAM to be employed in a variety of applications. For example, the ReRAM is embedded in a PCB, instead of being mounted on a surface thereof. Mounting discrete components on board in the case of a PCB may be costly, and the ReRAM design herein may avoid that challenge and allow the PCB to have additional space on the surface to have additional functionalities. Additionally, the ReRAM described herein may allow introduction of certain amount of the non-volatile memory to a PCB. Thus, the ReRAM described herein may be employed as, or as a part of, a memory for PCB identify (“ID”) information, digital signature, security to protect authentic PCB, etc. In one example, the ReRAM configuration described herein may allow introduction of non-write trace ID for a PCB.

The ReRAM, with memristor as one example, described herein may be accessed using any suitable technique. For example, one or both of the first and second electrodes may be electrically connected to another device, or another component of the device the memristor is a part of, accessing the memristor. The connection may, for example, be a via filled with a conductive material. The connection may, for example, be a metal wire.

The ReRAM, with memristor as one example, described herein may have an Off-to-On programming ratio of at least about 2—e.g., at least about 5, 10, 20, 40, 60, 80, 100, 150, 200 500, 1000, 1500, or higher. Other values are also possible. In one example, the memristor described herein has an Off-to-On programming ratio of between about 2 and about 150—e.g., between about 5 and about 100, etc. In one example, the Off-to-On programming is between 2 and about 10—e.g., between about 3 and about 9, between about 4 and about 8, between about 5 and about 7, etc. In one example, the Off-to-On ratio is 10.

In one example, the memristor (as one example of ReRAM) described herein is not a nano-sized memristor (the size is with respect to the largest dimension thereof). For example, as described herein, the memristor described herein may have a largest dimension that is in the micrometer range. For example, the memristor described herein may have memory states “1” and “0” digital states for the resistance difference, instead of analog computing, which may demand precise control for the analog value performance. In one example, the micrometer sized memristor described herein needs less stringent electrical demands for switching speed, current, power, and voltage, in comparison to a nano-sized memristor. In one example, the electrical demands for switching speed are greater than about 1 nm, the current greater than about 1 μA, the power greater than about 1 μJ, and the voltage greater than about 3 V. Additionally, in one example, the micrometer-sized memristor described herein is less expensive with respect to material cost and fabrication cost than the nano-sized counterpart.

### Additional Notes

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

All definitions, as defined and used herein, should be understood to control over dictionary definitions, definitions in documents incorporated by reference, and/or ordinary meanings of the defined terms.

The indefinite articles “a,” “an,” “the” as used herein in this disclosure, including the claims, unless clearly indicated to the contrary, should be understood to encompass both singular and plural. Any ranges cited herein are inclusive.

The terms “substantially” and “about” used throughout this disclosure, including the claims, are used to describe and account for small fluctuations, such as due to variations in processing. For example, they may refer to less than or equal to ±5%, such as less than or equal to ±2%, such as less than or equal to ±1%, such as less than or equal to ±0.5%, such as less than or equal to ±0.2%, such as less than or equal to ±01%, such as less than or equal to ±0.05%.

Concentrations, amounts, and other numerical data may be expressed or presented herein in a range format. Such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “1 weight % (wt %) to 5 wt %” should be interpreted to include not only the explicitly recited values of 1 wt % to 5 wt %, but also include individual values and sub-ranges within the indicated range. Thus, included in this numerical range are individual values, such as 2, 3.5, and 4, and sub-ranges, such as from 1-3, from 2-4, and from 3-5, etc. This same principle applies to ranges reciting only one numerical value. Furthermore, such an interpretation should apply regardless of the breadth of the range or the characteristics being described.

The phrase “and/or,” as used herein in this disclosure, including the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” or “including” may refer, in one example, to A only (optionally including elements other than B); in another example, to B only (optionally including elements other than A); in yet another example, to both A and B (optionally including other elements), etc.

As used in this disclosure, including the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms dearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

In this disclosure, including the claims, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent examining Procedures, §2111.03.

The claims should not be read as limited to the described order or elements unless stated to that effect. It should be understood that various changes in form and detail may be made by one of ordinary skill in the art without departing from the spirit and scope of the appended claims. All examples that come within the spirit and scope of the following claims a equivalents thereto are claimed.

What is claimed:

1. An article, including:
a first electrode;
a switching layer disposed over at least a portion of the first electrode, the switching layer including a metal oxide; and
a second electrode disposed over at least a portion of the switching layer;
wherein
the first electrode, the switching layer, and the second electrode are parts of a resistive random-access memory; and
one or both of the first electrode and the second electrode is a part of a layer of a printed circuit board.

2. The article of claim 1, wherein one or both of the first electrode and the second electrode is selected from the group consisting of platinum, copper, aluminium, titanium, tantalum, cobalt, nickel, molybdenum, tungsten, chromium, niobium, hafnium, zirconium, ruthenium, and iridium, or an alloy, or a nitride, or an oxide thereof.

3. The article of claim 1, further including any of the following:
(i) a first electrode interface layer, including one or both of a nitride and an oxide of a metal selected from the group consisting of copper, aluminium, titanium, tantalum, cobalt, zinc, nickel, iron, yttrium, silicon, gallium, molybdenum, tungsten, chromium, niobium, hafnium, zirconium, ruthenium, platinum, iridium, and combinations thereof; and
(ii) a second electrode interface layer, including one or both of a nitride and an oxide of a metal selected from the group consisting of copper, aluminium, titanium, tantalum, cobalt, zinc, nickel, iron, yttrium, silicon, gallium, molybdenum, tungsten, chromium, niobium, hafnium, zirconium, ruthenium, platinum, indium, tin, iridium, and combinations thereof.

4. The article of claim 1, wherein the metal oxide is selected from the group consisting of tantalum oxide, zinc oxide, zirconium oxide, gallium oxide, hafnium oxide, titanium oxide, tungsten oxide, copper oxide, vanadium oxide, iron oxide, strontium titanate, lithium niobate, niobium oxide, aluminium copper silicon metal oxide, and combinations thereof.

5. The article of claim 1, wherein the resistive random-access memory has a largest dimension that is between about 1 μm and about 100 m.

6. The article of claim 1, wherein the resistive random-access memory is a memristor.

7. A printed circuit board, including a plurality of resistive random-access memories including the article of claim 1.

8. A method of manufacturing, including:
forming a first electrode from a portion of a first layer of printed circuit board;
forming a switching layer over a portion of the first electrode, the switching layer including a metal oxide; and
forming over a portion of the switching layer a second electrode, wherein the second electrode is a part of a second layer of the printed circuit board;
wherein the first electrode, the switching layer, and the second electrode are parts of a resistive random-access memory embedded in the printed circuit board.

9. The method of claim 8, wherein forming the switching layer includes any of chemical vapor deposition, physical vapor disposition, oxidation and a sol-gel process.

10. The method of claim 8, further including any of the following:
forming a first electrode interface layer over the first electrode, the first electrode interface layer including one or both of a nitride and an oxide of a metal selected from the group consisting of copper, aluminium, titanium, tantalum, cobalt, zinc, nickel, iron, yttrium, silicon, gallium, molybdenum, tungsten, chromium, niobium, hafnium, zirconium, ruthenium, platinum, iridium, and combinations thereof, and
forming a second electrode interface layer over the second electrode, the second electrode interface layer, including one or both of a nitride and an oxide of a metal selected from the group consisting of copper, aluminium, titanium, tantalum, cobalt, zinc, nickel, iron, yttrium, silicon, gallium, molybdenum, tungsten, chromium, niobium, hafnium, zirconium, ruthenium, platinum, indium, tin, iridium, and combinations thereof.

11. The method of claim 8, further including repeating the steps one or more times and forming the remainder of the printed circuit board, such that the formed printed circuit board includes a plurality of the resistive random-access memories.

12. The method of claim 8, wherein the first electrode is formed on a substrate substantially free of elemental silicon.

13. A method of manufacturing, including:
disposing a resist over a clad& g layer including a first metal-containing material, the cladding layer disposed over a substrate that is one layer of a printed circuit board;
etching, using a first mask, at least a portion of the resist and a portion of the cladding layer to form a first electrode, which is disposed over the substrate;
disposing an oxide layer including a metal oxide over at least a portion of the first electrode and a portion of the substrate;
disposing a second metal-containing material over the oxide layer;
etching, using a second mask, at least a portion of the second metal-containing material and a portion of the oxide layer to form respectively a second electrode and a switching layer, the second electrode disposed over the switching layer including the metal oxide, the switching layer disposed over the first electrode,
whereby a resistive random-access memory including the first electrode, the switching layer, and the second electrode is formed embedded in the printed circuit board.

14. The method of claim 13, wherein disposing the oxide includes any of chemical vapor deposition, physical vapor disposition, oxidation, and a sol-gel process.

15. The method of claim 13, wherein the resistive random-access memory is a memristor.
